(19) United States
(12) Patent Application Publication
(10) Pub. No.: US 2023/0327606 A1
(43) Pub. Date: Oct. 12, 2023

(54) PHYSIOLOGICAL SIGNAL DETECTION SYSTEM

(71) Applicant: NATIONAL TAIWAN UNIVERSITY OF SCIENCE AND TECHNOLOGY, Taipei City (TW)

(72) Inventors: CHAO-HSIUNG TSENG, Taipei City (TW); YEN-TING LEE, Taipei City (TW)

(21) Appl. No.: 17/984,644

(22) Filed: Nov. 10, 2022

(30) Foreign Application Priority Data
Apr. 7, 2022 (TW) 111113326

(51) Int. Cl. H03C 1/00; H03C 3/09

(52) U.S. Cl. CPC H03C 1/00; H03C 3/09; H03C 5/00

(57) ABSTRACT

A physiological signal detection system is disclosed. The physiological signal detection system includes a measurement module, a signal processing module, and a microcontroller. The measurement module measures a subject in a non-contact manner to obtain a frequency modulation signal. The signal processing module is electrically connected to the measurement module, and the signal processing module includes a Mohr discriminator, which is used to demodulate the frequency modulation signal to obtain a physiological signal. The microcontroller is electrically connected to the signal processing module for converting and obtaining a digital physiological signal.

### BACKGROUND OF THE INVENTION

### 1. Field of the Invention

The present invention relates to a physiological signal detection system, and more particularly, to a physiological signal detection system that measures a subject in a non-contact manner.

2. Description of the Related Art

Nowadays, people's demand for better self-monitoring of their physical conditions is increasing day by day, and pulse and blood pressure are the most intuitive human vital signs. For average human subjects, pulse and blood pressure are usually measured with non-invasive blood pressure measurement technology. The non-invasive blood pressure measurement technology can be a mercury sphygmomanometer or an electronic sphygmomanometer. However, a subject of the sphygmomanometer must wear a compression device to pressurize an arm or another limb. The pressure of the compression device must be able to block the blood flow and thus may cause discomfort to the user.

Therefore, in the prior art, there is a device for measuring the pulse of a subject in a non-compressive manner. For example, an electrocardiography (ECG) method or a photoplethysmography (PPG) method is used, The electrocardiography method is used with professional medical equipment by applying patch electrodes or hand clip sensing devices to measure the subject, but the application of such methods often causes discomfort to the subject. The photoplethysmography method uses light to measure changes in blood flow in the blood vessels under different conditions. When the light illuminates the blood vessels near the test site, the diastolic and systolic pressure generated by the heart will pressurize the blood vessel walls, causing changes in light reflection. However, different skin tones and wavelengths of light will have different amounts of reflection, and the diodes that receive the signals are susceptible to interference from external light sources, resulting in measurement errors.

Therefore, it is necessary to propose a new physiological signal detection system to solve the deficiencies of the prior art.

### SUMMARY OF THE INVENTION

It is a main object of the present invention to provide a measurement module which measures a subject in a non-contact manner.

In order to achieve the above object, a physiological signal detection system is disclosed to measure a physiological signal of a subject. The physiological signal detection system includes a measurement module, a signal processing module, and a microcontroller. The measurement module measures a subject in a non-contact manner to obtain a frequency modulation signal. The signal processing module is electrically connected to the measurement module, and the signal processing module includes a Mohr discriminator, which is used to demodulate the frequency modulation signal to obtain a physiological signal. The microcontroller is electrically connected to the signal processing module for converting and obtaining a digital physiological signal.

### BRIEF DESCRIPTION OF THE DRAWINGS

FIG. 1 illustrates a structural view of a physiological signal detection system of the present invention;

FIG. 2A illustrates a structural view of a measurement module of the first embodiment of the present invention;

FIG. 2B illustrates a circuit structure view of the measurement module of the first embodiment of the present invention; FIG. 2C illustrates a side view of the substrate-integrated waveguide resonator of the first embodiment of the present invention;

FIG. 3A illustrates a structural view of the measurement module of the second embodiment of the present invention;

FIG. 3B illustrates a circuit structure diagram of the measurement module according to the second embodiment of the present invention; and

FIG. 4 illustrates a circuit structure view of the Mohr discriminator of the present invention.

### DETAILED DESCRIPTION OF THE PREFERRED EMBODIMENTS

In order to make the structure and characteristics as well as the effectiveness of the present invention further understood and recognized, the detailed description of the present invention is provided as follows along with embodiments and accompanying figures.

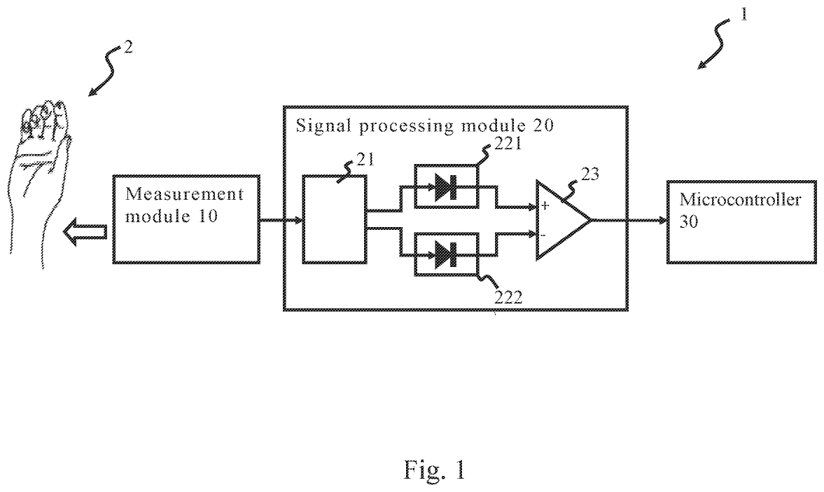

Please refer to FIG. 1 for a structural view of a physiological signal detection system of the present invention.

In an embodiment of the present invention, the physiological signal detection system 1 can be disposed in a smart wearable device or implemented as a standalone medical instrument. The physiological signal detection system 1 includes a measurement module 10, a signal processing module 20, and a microcontroller 30. The measurement module 10 uses a non-contact method to measure the finger, wrist or another part of the body of the subject 2 so as to measure the blood vessel pulse waveform of the subject 2, thereby obtaining the frequency modulation signal. The detailed circuit structure of the measurement module 10 will be described in detail later. The signal processing module 20 is electrically connected to the measurement module 10 and cooperates with the measurement module 10 to perform frequency demodulation on the frequency modulation signal to obtain the physiological signal. The microcontroller 30 is electrically connected to the signal processing module 20 to receive the amplified physiological signal, to convert the amplified physiological signal into a digital physiological signal, and then to transmit the digital physiological signal to other modules for operation.

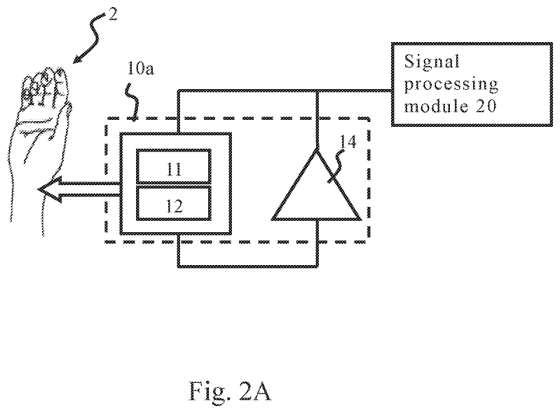

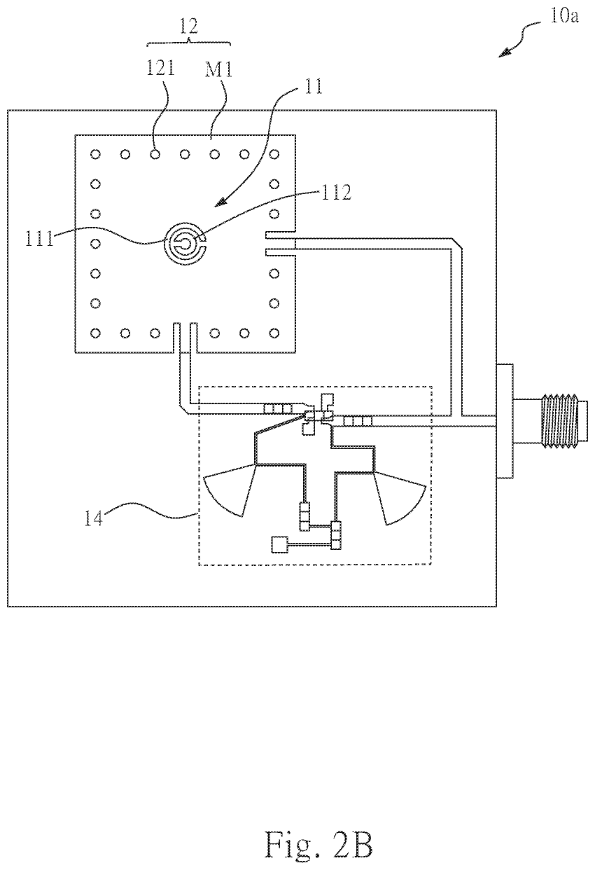

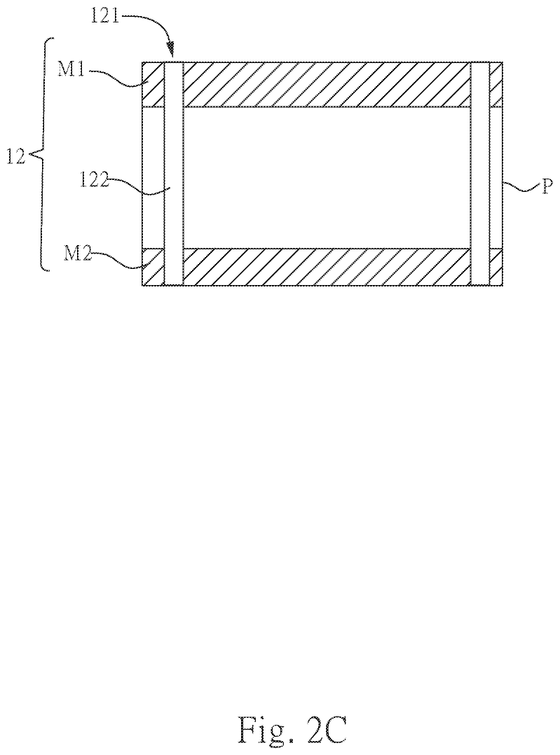

For one of the detailed structures of the measurement module 10, please refer to FIG. 2A for a structural view of a measurement module of the first embodiment of the present invention, FIG. 2B for a circuit structure view of the measurement module of the first embodiment of the present invention, and FIG. 2C for a side view of the substrate-integrated waveguide resonator of the first embodiment of the present invention.

In the first embodiment of the present invention, the measurement module measurement module 10a includes a complementary split ring resonator (CSRR) 11, a substrate integrated waveguide (SIW) resonator 12, and the radio-frequency bipolar transistor amplifier 14. The complementary split ring resonator 11 is mainly composed of a metal plane having a first C-shaped metal slot line 111 and a second C-shaped metal slot line 112 concentrically arranged and corresponding with each other at its center, wherein there are cross-mappings between the metal parts and the apertures of the two C-shaped metal slot lines 111 and 112. The complementary split ring resonator 11 can generate a periodic resonance frequency deviation according to the micro-vibration caused by the blood flow inside the finger, wrist or other parts of the subject 2, without direct contact with the subject 2. The substrate integrated waveguide resonator 12 has a first metal layer M1, a second metal layer M2, a plurality of metal pilot holes 121, and a plurality of vias 122. As shown in FIG. 2C, there is a circuit board P disposed between the first metal layer M1 and the second metal layer M2, and the first metal layer M1 and the second metal layer M2 are both 17 μm in thickness, but the present invention is not limited thereto. The surface of the first metal layer M1 is embedded in the first C-shaped metal slot line 111 and the second C-shaped metal slot line 112, and the plurality of metal pilot holes 121 are disposed in the first metal layer M1 and the second metal layer M2 to connect the first metal layer M1 and the second metal layer M2 by the plurality of vias 122. The plurality of metal pilot holes 121 and the plurality of vias 122 can be arranged in a rectangular shape, but the present invention is not limited thereto. With the above structure, a substrate integrated waveguide resonator 12 can be formed. Since the cavity resonator has the largest electric field energy distribution at the center of the plurality of metal pilot holes 121 it can be used to couple the electric field to the first C-shaped metal slot line 111 and the second C-shaped metal slot line 111, and also to effectively limit the electric field energy to be radiated only from the first C-shaped metal slot line 111 and the second C-shaped metal slot line 112. In addition, the substrate integrated waveguide resonator 12 adopts a coplanar waveguide (CPWG) structure to implement the energy output and input terminals of the resonator. In the first embodiment of the present invention, the size of the rectangle enclosed by the plurality of metal pilot holes 121 of the substrate integrated waveguide resonator 12 can be adjusted first, and then the sizes of the two C-shaped metal slot lines 111 and 112 of the complementary split ring resonator 11 are adjusted. In this way, a resonant cavity is formed by combining the complementary split ring resonator 11 and the substrate; integrated waveguide resonator 12, and the resonant cavity will have the greatest electric field energy at the center of the metal plane when the resonance frequency is, for example, 5.8 GHz. In addition, when the electric field of the complementary split ring resonator 11 is perpendicular to the metal plane, the substrate integrated waveguide resonator 12 also has the largest electric field energy at the center. The substrate integrated waveguide resonator 12 is used for effectively feeding energy into the complementary split ring resonator 11 placed in the middle of the metal plane such that the complementary split ring resonator 11 can radiate the electric field, and the radiation area is limited in the complementary split ring resonator 11 region. Therefore, the combination of the complementary split ring resonator 11 and the substrate integrated waveguide resonator 12 provides advantages of energy concentration and reduced radiation area so that the subject 2 can easily align his/her finger, wrist or another part of the body within the area where the measurement module 10a has the highest sensitivity.

The radio-frequency bipolar transistor amplifier 14 is electrically connected to the joint structure of the complementary split ring resonator 11 and the substrate integrated waveguide resonator 12 and is used for amplifying the loop gain and offsetting the energy loss caused by the passive components, thereby increasing the energy and satisfying the Barkhausen oscillation criteria to form an oscillator. In the first embodiment of the present invention, the radio-frequency bipolar transistor amplifier 14 is composed of microstrip lines and components such as resistors and capacitors mounted by using surface mounted technology (SMT). It should be noted that the structure of the radio-frequency bipolar transistor amplifier 14 used in FIG. 2B is only for illustration, and the present invention is not limited to the use of radio frequency amplifiers having the same circuit structure, as long as these amplifiers can achieve the same purpose of the present invention.

Therefore, the measurement module 10a of the first embodiment of the present invention uses the near-field self-injection-locked (NFSIL) technique as a sensing mechanism. Since the volume of the skin around the blood vessels of the subject 2 will change periodically due to the vascular pulse waveform, then according to the perturbation theory, when the volume of the skin of the subject 2 changes, the dielectric constant ire the area will change periodically, with the result that the resonance frequency of the complementary split ring resonator 11 will he periodically shifted to correspond to different phases. After the phase shift signal is injected into the oscillator, then according to the injection locking principle, the measurement module 10a can obtain the frequency modulated output signal.

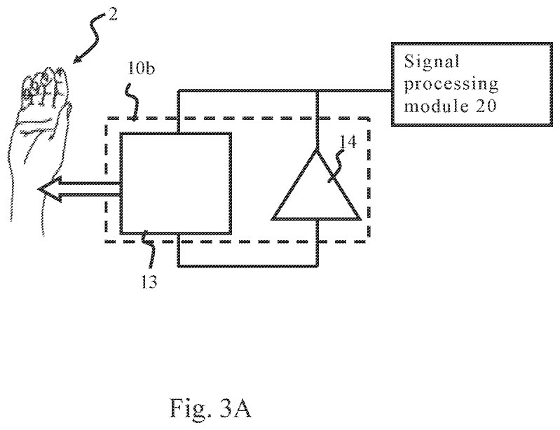

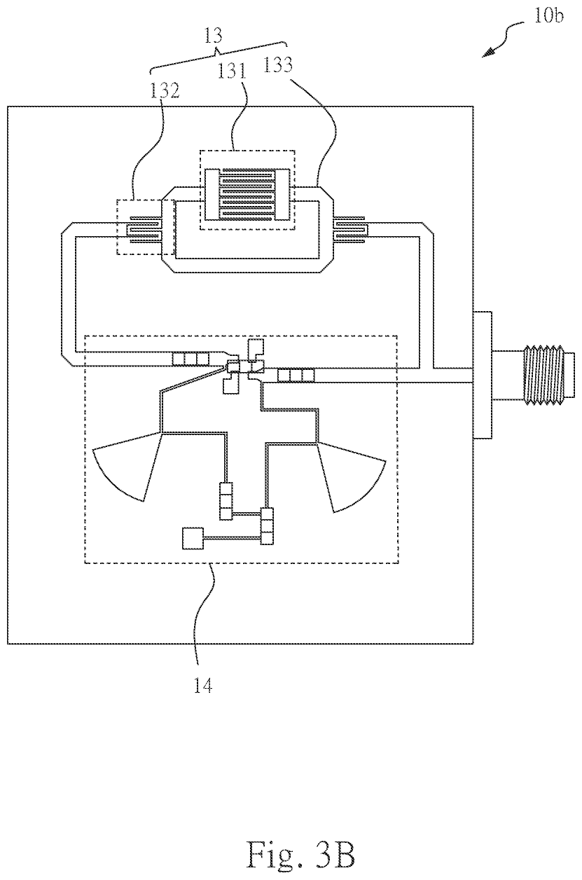

Next, please refer to FIG. 3A for a structural view of the measurement module of the second embodiment of the present invention and FIG. 3B for a circuit structure diagram of the measurement module of the second embodiment of the present invention.

In the second embodiment of the present invention, the measurement module 10b includes an interdigitated-electrodes split-ring resonator (IDE-SRR) 13 and a radio-frequency bipolar transistor amplifier 14. The interdigitated-electrodes split-ring resonator 13 has a sensing area 131, a feeding area 132, and an annular metal strip line 133. The sensing area 131 has a plurality of metal lines alternately arranged such that the plurality of alternately arranged metal lines will resonate with the annular metal strip line 133 on the periphery. The feeding area 132 adopts an interdigital capacitor structure and has a plurality of metal lines arranged alternately. After the lengths, widths or spacings of the above-mentioned metal lines are adjusted, the scattering parameter characteristics and resonance frequencies of the interdigitated-electrodes split-ring resonator 13 can be consistent with the expected results. For example, when the resonance frequency of the resonator is set at 5.8 GHz, the sensing area 131 has 10 metal lines alternately arranged, the length of each metal line is 3.75 mm, and the width and spacing are 0.2 mm; the feeding area 132 has 5 metal lines arranged alternately, the length of each metal line is 2.3 mm, the width of the most central metal line is 0.3 mm, and the width and spacing of the rest are 0.2 mm. However, the above values are used only as an embodiment, and the present invention does not limit the values of the number, length, width or spacing of the metal wires.

The interdigitated-electrodes split-ring resonator 13 is electrically connected to the radio-frequency bipolar transistor amplifier 14 to form an oscillator. Therefore, when the sensing area 131 of the interdigitated-electrodes split-ring resonator 13 is brought close to the finger, wrist or another part of the body, the oscillator will output a frequency modulation signal. Since the technology of the frequency-amplifier bipolar transistor radio 14 described here is the same as that of the first embodiment of the present invention, it will not be further explained here. Compared with the measurement module 10a of the first embodiment, the measurement module 10b of the second embodiment of the present invention has the advantages of a reduced sensor area, a larger sensing area, and a more uniform electric field distribution.

In are embodiment of the present invention, the signal processing module signal processing module 20 can comprise a Mohr discriminator 21, a first packet amplitude detector 221, a second packet amplitude detector 222, and a differential amplifying element 23. The frequency modulation signal output from the measurement module 10a or 10b is converted into an amplitude modulation signal by the Mohr discriminator 21, and then the amplitude modulation signal is transmitted to the first packet amplitude detector 221 and the second packet amplitude detector 222 for the first packet amplitude detector 221 and the second packet amplitude detector 222 to capture packets of two amplitude demodulation signals respectively. Then the differential amplifying element 23 performs a subtraction operation on the two captured input signals and amplifies the resulting signals so that the physiological signal can be more easily sensed at the output end of the processing module 20.

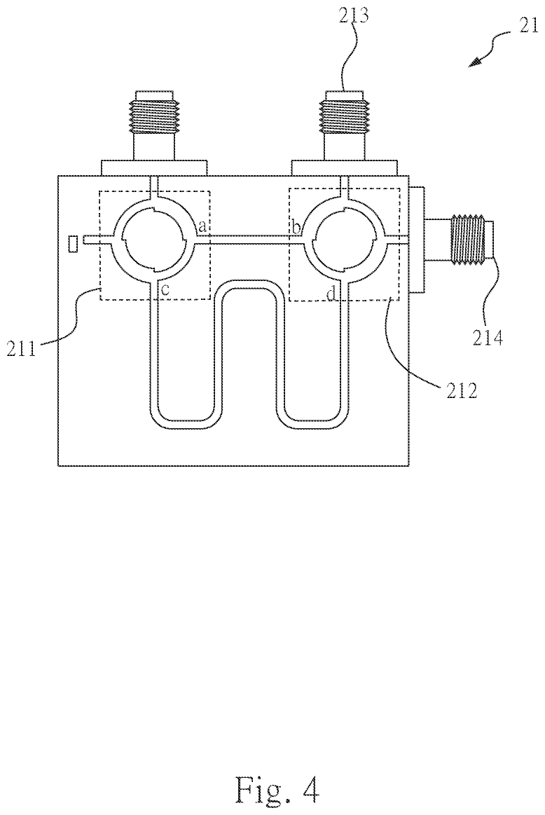

Finally, for the detailed circuit structure of the Mohr discriminator 21, please refer to FIG. 4, which illustrates a circuit structure view of the Mohr discriminator of the present invention.

The Mohr discriminator 21 includes a first branch-line coupler 211 and a second branch-line coupler 212. In order to reduce the area occupied, circular branch couplers are adopted to form the first branch-line coupler 211 and the second branch-line coupler 212 in FIG. 4, but the present invention is not limited to this configuration. Air upper output a of the first branch-line coupler 211 is connected to an upper input b of the second branch-line coupler 212 through a simple microstrip transmission line, and a lower output c of the first branch-line coupler 211 is connected to a lower input d of the second branch-line coupler 212 through a more tortuous microstrip transmission line or a delay line, thereby allowing the upper and the lower micros-trip transmission lines to have a phase difference with each other. Afterwards, the Mohr discriminator 21 uses a first signal output end 213 and a second signal output end 214 to output signals. The first packet amplitude detector 221 and the second packet amplitude detector 222 are connected to the first signal output end 213 and second signal output end 214 of the Mohr discriminator 21 respectively to convert the RF signal into a DC output signal. Finally, the differential amplifying element 23 is used as an amplifier to amplify and output the difference in amplitude response generated by the Mohr discriminator 21 to obtain a physiological signal.

It can be seen from the above description that the frequency modulation signal measured by the measurement module 10 will be processed by the signal processing module 20 to obtain the physiological signal, and then the physiological signal will finally be converted into a digital physiological signal by the microcontroller 30. The physiological signal detection system 1 of the present invention can accurately calculate the physiological signal of the subject 2 without directly contacting the subject 2 to obtain the blood vessel pulse waveform of the subject 2, thereby further obtaining data such as the pulse rate of the subject 2.

It should be noted that although the present invention is disclosed above by embodiments, the embodiments are merely illustrative and not restrictive of the present invention. Equivalent implementation of, or equivalent changes made to, without departing from the spirit of the present invention must be deemed to fall within the scope of the present invention. Accordingly, the legal protection for the present invention should be defined by the appended claims.

What is claimed is:

1. A physiological signal detection system for detecting a physiological signal of a subject, the physiological signal detection system comprising:
a measurement module measuring the subject in a non-contact manner to obtain a frequency modulation signal;
a signal processing module electrically connected to the measurement module, the signal processing module including a Mohr discriminator for demodulating the frequency modulation signal to obtain a to physiological signal; and
a microcontroller electrically connected to the signal processing module for converting and obtaining a digital physiological signal.

2. The physiological signal detection system as claimed in claim 1, wherein the Mohr discriminator comprises a first branch-line coupler and a second branch-line coupler to provide a first signal output end and a second signal output end.

3. The physiological signal detection system as claimed in claim 2, wherein the signal processing module further comprises a first packet amplitude detector and a second packet amplitude detector connected to the first signal output end and the second signal output end respectively to generate a first amplitude response and a second amplitude response respectively.

4. The physiological signal detection system as claimed in claim 3, wherein the signal processing module further comprises a differential amplifying element electrically connected to the first packet amplitude detector and the second packet amplitude detector, the differential amplifying element performing a difference operation on the first and the second amplitude response generated by the first packet amplitude detector and the second packet amplitude detector to obtain a resulting signal, and then to perform an amplifying operation to the resulting signal.

5. The physiological signal detection system as claimed in claim 1, wherein the measurement module comprises:
a complementary split ring resonator (CSRR) comprising a first C-type metal slot line and a second C-type metal slot line, the first C-type metal slot line and the second C-type metal slot line being arranged symmetrically with each other to detect the physiological signal;
a substrate integrated waveguide (SIW) resonator having a first metal layer, a second metal layer and a plurality of metal pilot holes, wherein the surface of the first metal layer is embedded with the first zip C-shaped metal slot line and the second C-shaped metal slot line, and the plurality of metal pilot holes are disposed on the first metal layer and the second metal layer to connect the first metal layer and the second metal layer by a plurality of vias; and
a radio-frequency bipolar transistor amplifier electrically connected with the complementary split ring resonator and the substrate integrated waveguide resonator to form an oscillator and to output the frequency modulation signal for detecting the physiological signal.

6. The physiological signal detection system as claimed in claim 1, wherein the measurement module comprises:
an interdigitated-electrodes split-ring resonator (IDE-SRR) comprising a sensing area, a feeding area and an annular metal strip line, both of the sensing area and the feeding area having a plurality of metal lines alternately arranged, wherein the sensing area is used for detecting the physiological signal; and
a radio-frequency bipolar transistor amplifier electrically connected to the interdigitated-electrodes split-ring resonator to form an oscillator and to output the frequency modulation signal for detecting the physiological signal.

7. The physiological signal detection system according to claim 1, wherein the physiological signal detection system is used for detecting a blood vessel pulse waveform of the subject.
